(19) United States
(12) Patent Application Publication
(10) Pub. No.: US 2020/0273794 A1
(43) Pub. Date: Aug. 27, 2020

(54) SEMICONDUCTOR DEVICE AND METHODS OF FORMING THE SAME

(71) Applicant: Taiwan Semiconductor Manufacturing Co., Ltd., Hsinchu (TW)

(72) Inventors: Mrunal A. Khaderbad, Hsinchu City (TW); Keng-Chu Lin, Ping-Tung (TW); Sung-Li Wang, Hsinchu County (TW); Shuen-Shin Liang, Hsinchu (TW); Yasutoshi Okuno, Hsinchu (TW); Yu-Yun Peng, Hsinchu (TW); Chia-Hung Chu, Taipei City (TW)

(73) Assignee: Taiwan Semiconductor Manufacturing Co., Ltd., Hsinchu (TW)

(21) Appl. No.: 16/283,838

(22) Filed: Feb. 25, 2019

(51) Int. Cl. H01L 23/522; H01L 29/78; H01L 21/768

(52) U.S. Cl. CPC H01L 23/5226; H01L 21/76843; H01L 21/76802; H01L 29/7851

(57) ABSTRACT

A semiconductor device and a method of forming the same are provided. The semiconductor device includes a substrate, a gate stack and a first dielectric layer over the substrate, a source/drain (S/D) region, a contact, and a via. The first dielectric layer is laterally aside and over the gate stack. The S/D region is located in the substrate on sides of the gate stack. The contact penetrates through the first dielectric layer to electrically connect to the S/D region. The via penetrates through a second dielectric layer to connect to the contact. The via includes a conductive layer and an adhesion promoter layer on sidewalls of the conductive layer. The conductive layer is in contact with the contact.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that may be created using a fabrication process) has decreased. This scaling down process generally provides benefits by increasing production efficiency and lowering associated costs.

Such scaling down has also increased the complexity of manufacturing ICs and, for these advances to be realized, similar developments in IC manufacturing are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the critical dimensions of the various features may be arbitrarily increased or reduced for clarity of discussion.

FIG. 1A to FIG. 1H are schematic cross-sectional views illustrating a method of forming a semiconductor device according to a first embodiment of the disclosure.

FIG. 2A to FIG. 2C are schematic cross-sectional views illustrating a method of forming a semiconductor device according to a second embodiment of the disclosure.

FIG. 3A to FIG. 3D are schematic cross-sectional views illustrating a method of forming a semiconductor device according to a third embodiment of the disclosure.

FIG. 4 to FIG. 6 schematic cross-sectional views respectively illustrating a semiconductor device according to some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein for ease of description to describe one element or feature's relationship to another element(s) or feature(s) as illustrated in the FIG.s. The spatially relative terms are intended to encompass different orientations of the device in use or operation in addition to the orientation depicted in the FIG.s. The apparatus may be otherwise oriented (rotated 90 degrees or at other orientations) and the spatially relative descriptors used herein may likewise be interpreted accordingly.

In some embodiments in which the semiconductor device is FinFET device, the fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

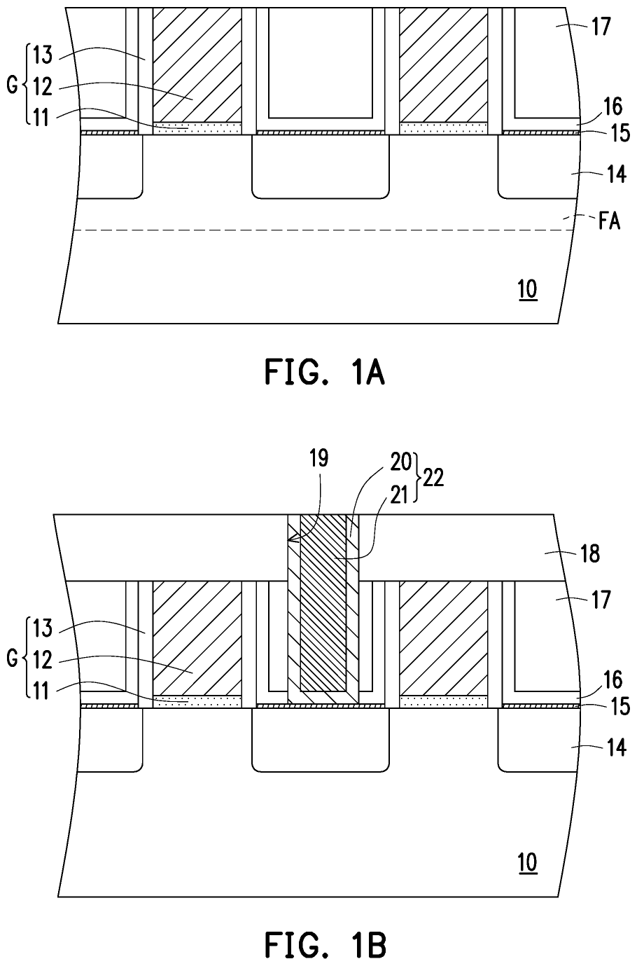

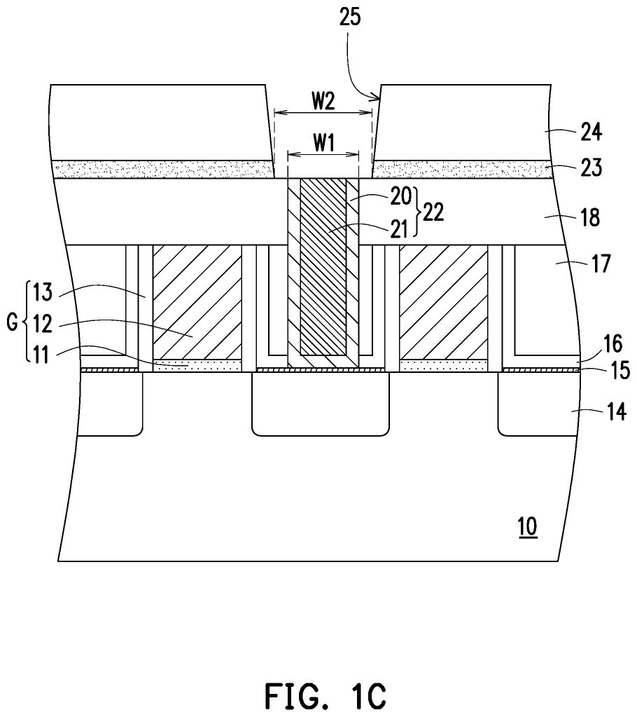

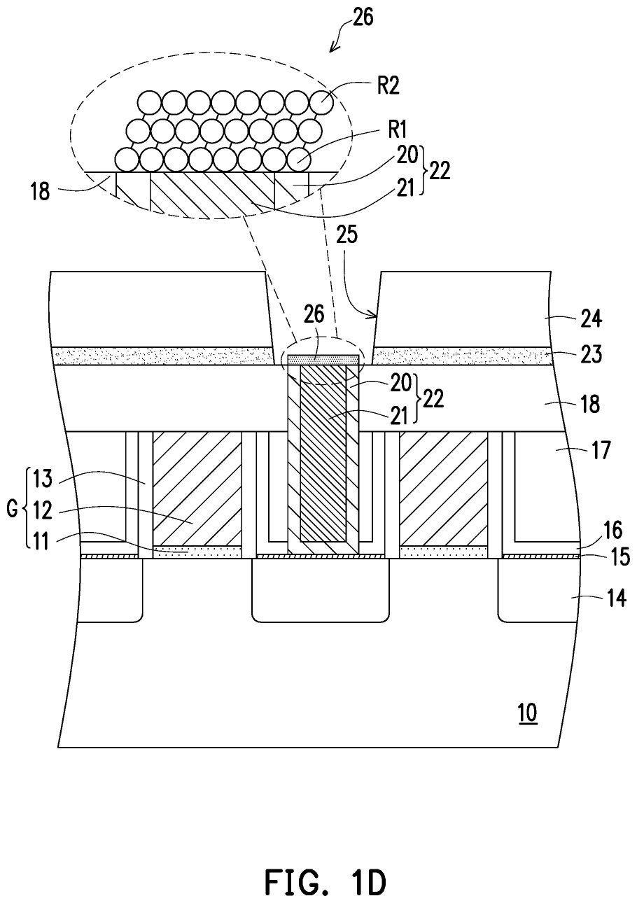

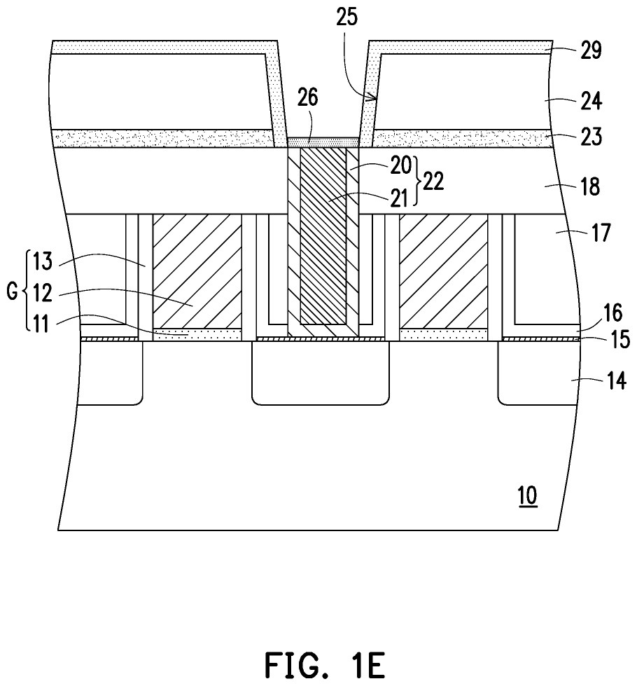

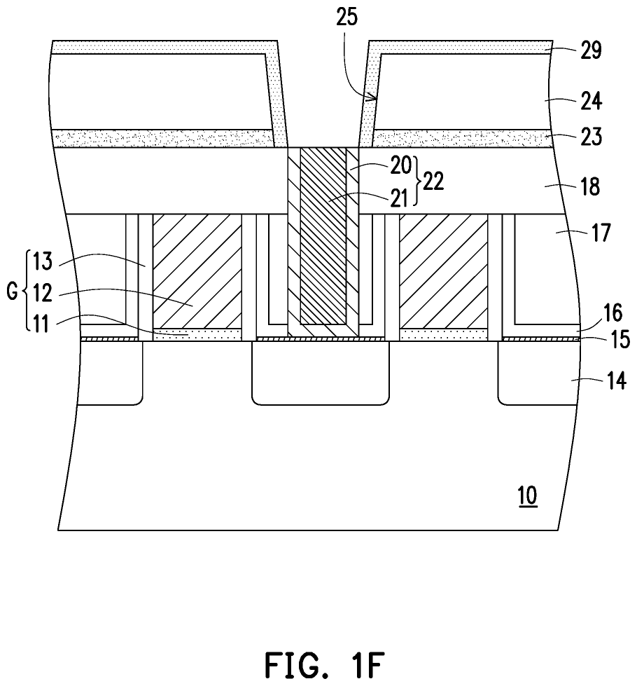

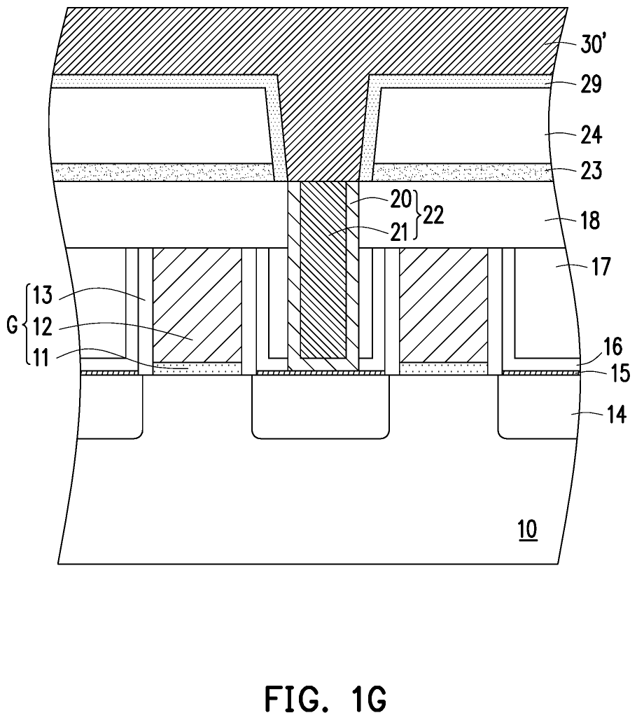

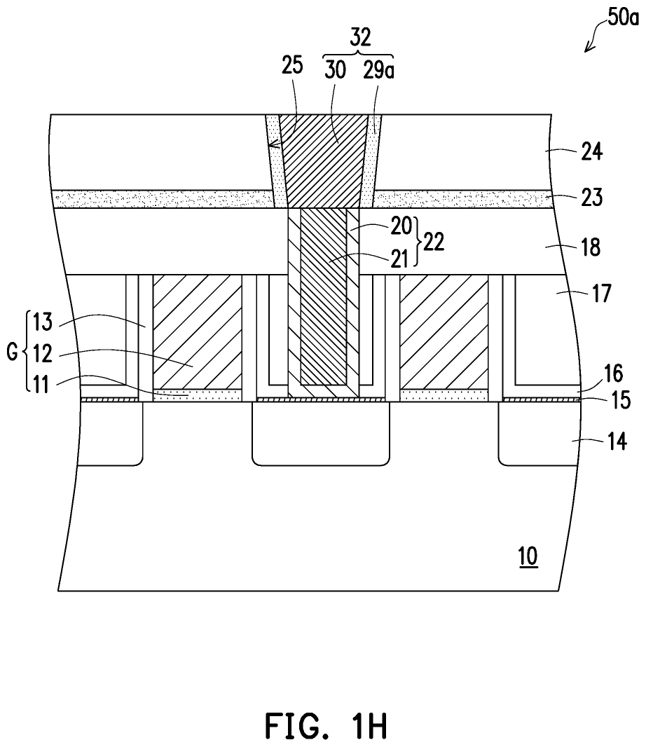

FIG. 1A to FIG. 1H are schematic cross-sectional views illustrating a method of forming a semiconductor device according to a first embodiment of the disclosure.

Referring to FIG. 1A, a substrate 10 is provided. In some embodiments, the substrate 10 is a semiconductor substrate, such as a bulk semiconductor substrate, a semiconductor-on-insulator (SOI) substrate, or the like, which may be doped (e.g., with a p-type or an n-type dopant) or undoped. The substrate 10 may be a wafer, such as a silicon wafer. Generally, an SOI substrate is a layer of a semiconductor material (such as silicon) formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 10 may include silicon; germanium; a compound semiconductor including silicon carbide (SiC), gallium arsenic (GaAs), gallium phosphide (GaP), indium phosphide (InP), indium arsenide (InAs), and/or indium antimonide (InSb); an alloy semiconductor including SiGe, GaAsP, AlInAs, AlGaAs, GalnAs, GaInP, and/or GaInAsP; or combinations thereof.

Depending on the requirements of design, the substrate 10 may be a P-type substrate, an N-type substrate or a combination thereof and may have doped regions therein. The substrate 10 may be configured for an NMOS device, a PMOS device, an N-type FinFET device, a P-type FinFET device, other kinds of devices (such as, multiple-gate transistors, gate-all-around transistors or nanowire transistors) or combinations thereof. In some embodiments, the substrate 10 for NMOS device or N-type FinFET device may include Si, SiP, SiC, SiPC, InP, GaAs, AlAs, InAs, InAlAs, InGaAs or combinations thereof. The substrate 10 for PMOS device or P-type FinFET device may include Si, SiGe, SiGeB, Ge, InSb, GaSb, InGaSb or combinations thereof.

In some embodiments in which the substrate 10 is configured for a FinFET device, the substrate 10 may include a plurality of fins FA, as shown the portion above the dashed line in FIG. 1A (for the sake of brevity, fins FA are merely illustrated in FIG. 1A and not shown in the following figures). The fins FA protrude from a top surface of the substrate 10. In some embodiments, the substrate 10 has an isolation layer formed thereon. The isolation layer covers lower portions of the fins FA and exposes upper portions of the fins FA. In some embodiments, the isolation layer is a shallow trench isolation (STI) structure.

In some embodiments, the substrate 10 has a plurality of gate stacks G formed thereon, source/drain (S/D) regions 14 formed therein, an etching stop layer 16 and a dielectric layer 17 formed thereon.

Still referring to FIG. 1A, the gate stack G may include a gate dielectric layer 11, a gate electrode 12 and spacers 13. The gate dielectric layer 11 may include silicon oxide, silicon nitride, silicon oxynitride, high-k dielectric materials, or combinations thereof. The high-k material may have a dielectric constant greater than about 4 or 10. In some embodiments, the high-k material includes metal oxide, such as ZrO₂, Gd₂O₃, HfO₂, BaTiO₃, Al₂O₃, LaO₂, TiO₂, Ta₂O₅, Y₂O₃, STO, BTO, BaZrO, HfZrO, HfLaO, HfTaO, HfTiO, a combination thereof, or a suitable material. In alternative embodiments, the gate dielectric layer 11 may optionally include a silicate such as HfSiO, LaSiO, AlSiO, a combination thereof, or a suitable material.

The gate dielectric layer 11 may be formed by a suitable technique such as a thermal oxidation process, a chemical vapor deposition (CVD) process, an atomic layer deposition (ALD) process, or combinations thereof. In some embodiments, the gate dielectric layer 11 is formed between the gate electrode 12 and the substrate 10, but the disclosure is not limited thereto. In some other embodiment, the gate dielectric layer 11 may be formed between the gate electrode 12 and the substrate 10, and between the gate electrode 12 and the spacers 13 to surround the sidewalls and bottom of the gate electrode 12. In some embodiments, an interfacial layer such as a silicon oxide layer may further be formed between the gate dielectric layer 11 and the substrate 10.

The gate electrode 12 may include doped polysilicon, undoped polysilicon, or metal-containing conductive material. In some embodiments, the gate electrode G includes a work function metal layer and a fill metal layer on the work function metal layer. The work function metal layer is an N-type work function metal layer or a P-type work function metal layer. In some embodiments, the N-type work function metal layer includes TiAl, TiAlN, or TaCN, conductive metal oxide, and/or a suitable material. In alternative embodiments, the P-type work function metal layer includes TiN, WN, TaN, conductive metal oxide, and/or a suitable material. The fill metal layer includes copper, aluminum, tungsten, or other suitable materials. In some embodiments, the gate electrode 12 may further include a liner layer, an interface layer, a seed layer, an adhesion layer, a barrier layer, a combination thereof or the like. The gate electrode 12 may be formed by formed by suitable processes such as ALD, CVD, physical vapor depositon (PVD), plating process, or combinations thereof.

The spacers 13 are disposed on sidewalls of the gate dielectric layer 11 and the gate electrode 12. The spacer 13 may be a single layer structure or a multi-layer structure. In some embodiments, the spacers 13 may be formed by the following processes: a spacer material layer is formed on the substrate 10 covering the gate electrodes 12, the spacer material layer includes SiO₂, SiN, SiCN, SiOCN, SiOR (wherein R is an alkyl group such as CH₃, C₂H₅ or C₃H₇), SiC, SiOC, SiON, combinations thereof or the like, and may be formed by a suitable deposition process such as CVD, ALD or the like. Thereafter, an etching process such as an anisotropic etching process is performed to remove a portion of the spacer material layer, and the spacers 13 on sidewalls of the gate electrodes 12 and gate dielectric layer 11 are remained.

S/D regions 14 are formed in the substrate 10 beside the gate stacks G. In some embodiments, the S/D regions 14 are doped regions configured for a PMOS device or P-type FinFET and include p-type dopants, such as boron, BF₂⁺, and/or a combination thereof. In alternative embodiments, the S/D regions 14 are doped regions configured for a NMOS device or N-type FinFET, and include n-type dopants, such as phosphorus, arsenic, and/or a combination thereof. The S/D regions 14 may be formed by an ion implanting process with the gate stack G as a mask. However, the disclosure is not limited thereto.

In some other embodiments, the S/D regions 14 are strained layers formed by epitaxial growing process such as selective epitaxial growing process. In some embodiments, recesses are formed in the substrate 10 on sides of the gate stack G, and the strained layers are formed by selectively growing epitaxy layers from the recesses. In some embodiments, the strained layers 14 include silicon germanium (SiGe), SiGeB, Ge, InSb, GaSb, InGaSb or combinations thereof for a P-type MOS or FinFET device. In alternative embodiments, the strained layers 16 include silicon carbon (SiC), silicon phosphate (SiP), SiCP, InP, GaAs, AlAs, InAs, InAlAs, InGaAs or a SiC/SiP multi-layer structure, or combinations thereof for an N-type MOS or FinFET device. In some embodiments, the strained layers 14 may be optionally implanted with an N-type dopant or a P-type dopant as needed.

In some embodiments, the top surfaces of the S/D regions 14 are substantially coplanar with the top surface of the substrate 10, but the disclosure is not limited thereto. In some other embodiments, the S/D regions 14 may further extend upwardly along the sidewalls of the corresponding spacers 13, and thus have top surfaces higher than the top surface of the substrate 10. In some embodiments, the depth of the S/D region 14 ranges from 3nm to 30nm, for example, but the disclosure is not limited thereto. The cross-sectional shape of the S/D region 14 shown in FIG. 1A is merely for illustration, and the disclosure is not limited thereto. The S/D region 14 may have any suitable shape as needed. In some embodiments, the substrate 10 may further include lightly doped regions formed therein. For example, lightly doped drain (LDD) regions may be formed adjacent to the S/D regions 14 in the substrate 10.

Still referring to FIG. 1A, in some embodiments, after the S/D regions 14 are formed and before forming the etching stop layer 16, a plurality of silicide layers 15 may be formed on the S/D regions 14. In some embodiments, the silicide layers 15 include nickel silicide (NiSi), cobalt silicide (CoSi), titanium silicide (TiSi), tungsten silicide (WSi), molybdenum silicide (MoSi), platinum silicide (PtSi), palladium silicide (PdSi), CoSi, NiCoSi, NiPtSi, Ir, PtIrSi, ErSi, Yb Si, PdSi, RhSi, or NbSi, or combinations thereof.

In some embodiments, the silicide layers 15 are formed by performing a self-aligned silicide (salicide) process including following steps. A metal layer is formed to at least cover the S/D regions 14. The material of the metal layer may include Ti, Co, Ni, NiCo, Pt, Ni(Pt), Ir, Pt(Ir), Er, Yb, Pd, Rh, Nb, TiSiN, or combinations thereof. Thereafter, an annealing process is carried out such that the metal layer is reacted with the S/D regions 14, so as to form the silicide layers 15. The unreacted metal layer is then removed. In some embodiments, the thickness of the silicide layer 15 ranges from 2nm to l0nm, for example, but the disclosure is not limited thereto.

Still referring to FIG. 1A, the etching stop layer 16 and the dielectric layer 17 are formed on the substrate 10 and laterally aside the gate stacks G. The etching stop layer 16 may also be referred to as a contact etch stop layer (CESL), and is disposed between the substrate 10 and the dielectric layer 17 and between the gate stack G and the dielectric layer 17. In some embodiments, the etching stop layer 16 includes SiN, SiC, SiOC, SiON, SiCN, SiOCN, or the like, or combinations thereof. The etching stop layer 16 may be formed by CVD, plasma-enhanced CVD (PECVD), flowable CVD (FCVD), ALD or the like.

The dielectric layer 17 includes a material different from that of the etching stop layer 16. In some embodiments, the dielectric layer 17 may also be referred to as an interlayer dielectric layer (ILD). In some embodiments, the dielectric layer 17 includes silicon oxide, carbon-containing oxide such as silicon oxycarbide (SiOC), silicate glass, tetraethylorthosilicate (TEOS) oxide, un-doped silicate glass, or doped silicon oxide such as borophosphosilicate glass (BPSG), fluorine-doped silica glass (FSG), phosphosilicate glass (PSG), boron doped silicon glass (BSG), combinations thereof and/or other suitable dielectric materials. In some embodiments, the dielectric layer 17 may include low-k dielectric material with a dielectric constant lower than 4, extreme low-k (ELK) dielectric material with a dielectric constant lower than 2.5 and may further include a small amount of high-k material with a dielectric constant higher than 4. In some embodiments, the low-k material includes a polymer based material, such as benzocyclobutene (BCB), FLARE®, or SILK®; or a silicon dioxide based material, such as hydrogen silsesquioxane (HSQ) or SiOF. The high-k dielectric material includes ZrO₂, HfO₂, for example. The dielectric layer 17 may be a single layer structure or a multi-layer structure. The dielectric layer 17 may be formed by CVD, PECVD, FCVD, spin coating or the like.

In some embodiments, the etching stop layer 16 and the dielectric layer 17 may be formed by forming etching stop material layer and dielectric material layer over the substrate 10 and the gate stacks G, and a planarization process is then performed, such that the top surfaces of the gate stacks G are exposed. In some embodiments, the top surface of the etching stop layer 16, the top surface of the dielectric layer 17 and the top surfaces of the gate stacks G are substantially coplanar with each other, but the disclosure is not limited thereto.

It is noted that, the gate electrode 12 may be formed by a gate first process which is formed before forming the spacers 13, or formed by a gate last process which is formed after the dielectric layer 17 is formed.

Referring to FIG. 1B, a dielectric layer 18 is formed over the substrate 10 to cover the top surfaces of the gate stacks G, the etching stop layer 16 and the dielectric layer 17. In some embodiments, the dielectric layer 18 may also be referred to as an interlayer dielectric layer (ILD). In some embodiments, the material of the dielectric layer 18 includes dielectric materials similar to, and may be the same as or different from those of the dielectric layer 17, which are not described again. The dielectric layer 18 may be formed by CVD, PECVD, FCVD, spin coating or the like. In some embodiments, the thickness of the dielectric layer 18 ranges from 1 nm to 10 nm, for example, but the disclosure is not limited thereto.

In some embodiments, a contact 22 is formed penetrating through the dielectric layer 18, the dielectric layer 17 and the etching stop layer 16 to electrically connect to the S/D regions 14. The contact 22 may be formed by the following processes. In some embodiments, the dielectric layer 18, the dielectric layer 17 and the etching stop layer 16 are patterned to form openings 19 (or called “contact holes”) corresponding to the S/D regions 14. In some embodiments, the patterning method includes photolithograph and one or more etching processes.

In some embodiments, after the dielectric layer 18 is formed, a patterned mask layer with openings is formed on the dielectric layer 18. The openings of the patterned mask layer correspond to the intended locations of the subsequently formed contact holes. The patterned mask layer is a patterned photoresist, for example. Thereafter, portions of the dielectric layer 18, the dielectric layer 17 and the etching stop layer 16 are removed by etching process (es) using the patterned mask layer as an etch mask, so as to form the openings 19.

In some embodiments, the opening 19 penetrates through the dielectric layer 18, the dielectric layer 17 and the etching stop layer 16 to expose the corresponding S/D region 14 or the silicide layer 15 on the S/D region 14. In some embodiments, the opening 19 has substantially vertical sidewalls, as shown in FIG. 1B, but the disclosure is not limited thereto. In alternative embodiments, the opening 19 have inclined sidewalls. Besides, the cross-sectional shape of the opening 19 may be square, rectangular, trapezoid or any other suitable shape as needed, and the disclosure is not limited thereto.

Still referring to FIG. 1B, the contact 22 is formed on the S/D region 14 within the opening 19. In some embodiments, the contact 22 includes a barrier layer 20 and a conductive layer (or referred to as conductive feature) 21. The barrier layer 20 may include titanium, tantalum, titanium nitride, tantalum nitride, manganese nitride or a combination thereof. The conductive layer 21 may include metal, such as tungsten (W), copper (Cu), Ru, Ir, Ni, Os, Rh, Al, Mo, Co, alloys thereof, combinations thereof or any metal material with suitable resistance and gap-fill capability. In some embodiments, the height of the contact 22 may range from 0.5 nm to 90 nm, but the disclosure is not limited thereto.

In some embodiments, a barrier material layer and a metal material layer are formed on the substrate 100 by sputtering, CVD, PVD, electrochemical plating (ECP), electrodeposition (ELD), ALD, or combinations thereof or the like. In some embodiments, the metal material layer is formed by a CVD process, during which the process temperature ranges from 50° C. to 500° C., the carrier gas may include Ar or N₂ with a flow rate ranging from 10-500 sccm, but the disclosure is not limited thereto. The barrier material layer and the metal material layer fill in the opening 19 and cover the top surface of the dielectric layer 18. Thereafter, a planarization step such as CMP is then performed to remove portions of the metal material layer and the barrier material layer over the dielectric layer 18, such that the top surface of the dielectric layer 18 is exposed. In some embodiments, the top surfaces of the barrier layer 20 and the conductive layer 21 are substantially coplanar with the top surface of the dielectric layer 18.

Still referring to FIG. 1B, in some embodiments, the barrier layer 20 surrounds sidewalls and bottom surface of the conductive layer 21. In other words, the barrier layer 20 is located between the conductive layer 21 and the S/D region 14, and between the conductive layer 21 and the dielectric layer 18/the dielectric layer 17/the etching stop layer 15. The barrier layer 20 serves as a diffusion barrier to prevent the diffusion of the metal atoms of the conductive layer 21.

Referring to FIG. 1C, an etching stop layer 23 and a dielectric layer 24 are sequentially formed over the substrate 10 by CVD, PECVD, FCVD, spin coating or the like. In some embodiments, the dielectric layer 24 may also be referred to as an interlayer dielectric layer (ILD). The materials of the etching stop layer 23 and the dielectric layer 24 may be selected from the same candidate materials of the etching stop layer 16 and the dielectric layer 17, respectively. The material of the etching stop layer 23 is different from the material of the dielectric layer 24 and the material of dielectric layer 18. In some embodiments, the etching stop layer 23 may be thinner than the dielectric layers 18 and 24. The thickness of the etching stop layer 23 ranges from lnm to 10 nm, for example, but the disclosure is not limited thereto. The thickness of the dielectric layer 24 may be the same as or different that of the dielectric layer 18.

An opening such as a via hole 25 is then formed in the dielectric layer 24 and the etching stop layer 23 to expose the contact 22. In some embodiments, the via hole 25 may also be a via trench. The via hole 25 may be formed by a photolithograph and one or more etching processes. In some embodiments, after the etching stop layer 23 and the dielectric layer 24 are formed, a patterned mask layer such as a patterned photoresist is formed on the dielectric layer 24. The patterned mask layer has openings correspond to the intended locations of the subsequently formed via hole 25. Thereafter, portions of the dielectric layer 24 and the etching stop layer 23 are removed by using the patterned mask layer as an etch mask, so as to form the via hole 25.

Still referring to FIG. 1C, in some embodiments, the sidewalls of the via hole 25 may be inclined, and the cross-sectional shape of the via hole may be trapezoid. In alternative embodiments, the sidewalls of the via hole 25 may be substantially vertical, and the cross-sectional shape of the via hole may be square, rectangular, or the like. However, the disclosure is not limited thereto.

In some embodiments, the via hole 25 exposes a top surface of the contact 22, and may further expose a portion of the top surface of the dielectric layer 18. In other words, the width W2 (such as, bottom width) of the via hole 25 may be larger than the width W1 (such as, top width) of the contact 22, but the disclosure is not limited thereto.

Referring to FIG. 1D, an inhibitor layer 26 is formed on the contact 22 exposed by the via hole 25. In some embodiments, the inhibitor layer 26 is a self-assembled monolayer (SAM) 26. The molecule of SAM 26 has a head group R1 showing a specific affinity for the material of the contact 22. The head group R1 refers to one end group of the molecule and may also be called as a terminal group. In some embodiments, the head group R1 is connected to an alkyl chain. The alkyl chain may include a liner alkyl chain or a branched alkyl chain. The carbon chain length (C-C)n of the alkyl chain may be adjustable to define critical dimension of the SAM 26, for example, to increase or decrease a thickness of the SAM 26.

Selection of the head group R1 is depending on the application of the SAM, and the material of the contact 22. In some embodiments, the head group R1 may include thiol (—SH), disulfide, dialkyl sulfide, —CN, —NH2, —P, —PO, —PO₃, —SeH, —SeSe, for example. In some embodiments, the SAM 26 may include din-alkyl sulfide, di-n-alkyl disulfide, 3-thiophenol, mercaptopyridine, mercaptoaniline, thiophene, cysteine, xanthate, thiocarbaminate, thiocarbamate, thiourea, mercaptoimidazole, alkanethiol (such as CH₃(CH₂)₁₅SH), alkaneselenol, combinations thereof or the like.

The SAM 26 may be formed by a vapor deposition process or a liquid deposition process. The SAM 26 is created by chemisorption of the hydrophilic head groups onto the contact 22, followed by a slow two-dimensional organization of hydrophobic head groups. SAM 26 adsorption may occur from solution by immersion of the structure shown in FIG. 1C into a dilute solution of, in one embodiment, an alkane thiol in ethanol. SAM 26 adsorption may also occur from a vapor phase. The adsorbed molecules initially form a disordered mass of molecules, and instantaneously begin to form crystalline or semicrystalline structures on the contact 22 in a monolayer. Owing to the specific affinity of the head group R1 of the SAM 26 to the material of the contact 22, and the SAM material will not react with the exposed dielectric layer 18, etching stop layer 23 and dielectric layer 24, the SAM 26 is selectively deposited on the contact 22, forming a metal complex in some embodiment. The SAM 26 may be deposited via spin-on coating from a solution of, for example, an alkane thiol in ethanol. The un-reacted portions of the SAM material on the surfaces of the dielectric layers 18/24 and etching stop layer 23 may be rinsed off using suitable solvent based rinse, remaining a layer of SAM 26 on the surfaces of the contact 22. It will be understood that a thickness of the SAM layer left on the contact 22 may be adjusted by adjusting the carbon chain length of the alkyl chain of the SAM. In some embodiments, the inhibitor layer (SAM) 26 is formed both on the conductive layer 21 and the barrier layer 20 of the contact 22, but the disclosure is not limited thereto. In alternative embodiments, the inhibitor layer 26 may be formed on the conductive layer 21 and not formed on the barrier layer 20.

Referring to FIG. 1E, an adhesion promoter layer 29 is formed on the exposed dielectric layer 18, etching stop layer 23 and the dielectric layer 24 through a selective deposition process. The material of the adhesion promoter layer 29 is different from the material of the barrier layer 20. In some embodiments, the material of the adhesion promoter layer 29 includes oxide or nitride, such as metal oxide, metal nitride, or combinations thereof. In some embodiments, the material of the adhesion promoter layer 29 may be a conductive material such as conductive metal oxide or a non-conductive material such as a dielectric material. The dielectric material may be low-k dielectric material, or high-k dielectric material. In some embodiments, the metal oxide includes RuO, (such as RuO₂), WOₓ, IrO₂, NiOₓ, TiOₓ, ReO₃, SrRuO₃, La_{o.3}Sr_{0.5}CoO₃, or combinations thereof, for example. The low-k dielectric material may include silicon oxide, silicon nitride, silicon oxynitride, or combinations thereof. The high-k dielectric material may include ZrO₂, HfO₂ or the like or a combination thereof. In some embodiments, the thickness of the adhesion promoter layer 29 ranges from 0.5 nm to 1 nm, for example, but the disclosure is not limited thereto.

The adhesion promoter layer 29 is formed by a selective deposition process such as a selective CVD or selective ALD process. In some embodiments, the precursor or/and reaction gas of the selective deposition process may adsorb on the dielectric layers 18/24 and etching stop layer 23 and conduct a reaction to form the adhesion promoter layer 29, and the precursor or/and the reaction gas would not absorb on the inhibitor layer 26. In some embodiments, the reaction mechanism of the selective deposition process and the property of the inhibitor layer 26 makes the adhesion promoter layer 29 only deposit on the surfaces of the dielectric layers 18/24 and the etching stop layer 23, and not deposit on the inhibitor layer 26 over the contact 22.

In some embodiments, the molecules of the inhibitor layer (SAM) 26 include specially designed functional groups to inhibit the adhesion promoter layer 29 deposition thereon. For example, the specially designed functional groups (such as terminal groups R2 shown in FIG. 1D) of the SAM may have hydrophobic properties, for example, the terminal groups R2 may include methyl (—CH₃), phenyl, pyrrole, tolyl, the like, or combinations thereof, which would not react with or adsorb the precursor or/and reaction gas used in the deposition process of the adhesion promoter layer 29, so as to inhibit the adhesion promoter layer 29 depositing on the inhibitor layer 26 over the contact 22. In some embodiments, the terminal group R2 is also referred to as tail group.

Referring to FIG. 1E to FIG. 1F, thereafter, the inhibitor layer 26 is removed by an etching process, such as wet etching, dry etching, or the like, or a combination thereof. The top surface of the contact 22 is exposed.

Referring to FIG. 1G, a conductive material layer 30′ is formed over the substrate 10. The conductive material layer 30′ fills in the via hole 25 and covers the top surface of the adhesion promoter layer, and is electrically connected to the contact 22. In some embodiments, the conductive material layer 30′ includes metal or metal alloy, such as Co, Cu, Ru, Ni, Al, Pt, Mo, W, Al, Ir, Os, alloy thereof, or combinations thereof. The forming method of the conductive material layer 30′ may include CVD, ALD, PVD, ECP, ELD, or the like or combinations thereof. In some embodiments, the conductive material layer 30′ is formed by a CVD process, during which the process temperature ranges from 50° C. to 500° C., the carrier gas may include Ar or N2 with a flow rate ranging from 10-500 sccm, but the disclosure is not limited thereto.

In some embodiments, the material of the adhesion promoter layer 29 is selected depending on the material of the conductive material layer 30′. In some embodiments, the adhesion promoter layer 29 includes a metal oxide correspond to the metal of the conductive material layer 30′, but the disclosure is not limited thereto. For example, the conductive material layer 30′ including Ru correspond to the adhesion promoter layer 29 including RuO₂, IrO₂, NiOx, TiOₓ, ReO3, SrRuO₃. The conductive material layer 30′ including W correspond to the adhesion promoter layer 29 including WOx. The conductive material layer 30′ including Co correspond to the adhesion promoter layer 29 including La_{0.5}Sr_{0.5}CoO₃. However, the disclosure is not limited thereto.

Referring to FIG. 1G to FIG. 1H, a planarization process (such as chemical mechanical polishing, CMP) is then performed to remove a portion of the conductive material layer 30′ over the top surface of the dielectric layer 24. In some embodiments in which the adhesion promoter layer 29 is a conductive layer, the planarization process is performed until the top surface of the dielectric layer 24 is exposed, that is, the adhesion promoter layer 29 over the top surface of the dielectric layer 24 is also removed by the planarization process. In some embodiments, after the planarization process, a adhesion promoter layer 29a and a conductive layer 30 are remained in the via hole 25. The top surface of the adhesion promoter layer 29a and the top surface of the conductive layer 30 are substantially coplanar with the top surface of the dielectric layer 24. However, the disclosure is not limited thereto.

Referring to FIG. 1H, in some embodiments, the adhesion promoter layer 29a and the conductive layer 30 constitute a via 32. The via 32 is located in the via hole 25 to electrically connect to the contact 22. In some embodiments, the height of the via 32 may range from 0.5 nm to 60 nm, but the disclosure is not limited thereto.

Still referring to FIG. 1H, a semiconductor device 50a is thus formed, the semiconductor device 50a includes the substrate 10, the gate stack G, the S/D regions 14, the etching stop layer 16, the dielectric layer 17, the dielectric layer 18, the etching stop layer 23, the dielectric layer 24, the contact 22 and the via 32. The S/D regions 14 are located in the substrate 10 and beside the gate stack G. In some embodiments, the S/D regions 14 include the silicide layers 15 formed thereon. The etching stop layer 16 and the dielectric layer 17 are located on the substrate 10 and laterally aside the gate stacks G. The dielectric layer 18, the etching stop layer 23 and the dielectric layer 24 are located over the gate stacks G and the dielectric layer 17.

The contact 22 penetrates through the dielectric layer 18, the dielectric layer 17 and the etching stop layer 16 to electrically connect to the S/D regions 14. In some embodiments, the contact 22 is landing on the silicide layer 15 of the S/D region 14. In some embodiments, the contact 22 includes a barrier layer 20 and a conductive layer 21. The barrier layer 20 surrounds sidewalls and bottom of the conductive layer 21 to serve as a diffusion barrier. The via 32 penetrates through the dielectric layer 24 and the etching stop layer 23 to electrically connect to the contact 22. In some embodiments, the cross sectional shape of the contact 22 and the via 32 may respectively be square, rectangular, trapezoid or any other suitable shape as needed, and the disclosure is not limited thereto.

In some embodiments, the via 32 includes the adhesion promoter layer 29a and the conductive layer 30. The conductive layer 30 is located on the electrically connect to the contact 22. In some embodiments, the bottom surface of the conductive layer 30 is in physical and electric contact with the top surfaces of the barrier layer 20 and the conductive layer 21 of the contact 22. The adhesion promoter layer 29a surrounds sidewalls of the conductive layer 30 and is laterally between the conductive layer 30 and the dielectric layer 24, and between the conductive layer 30 and the etching stop layer 23. The bottom surface of the adhesion promoter layer 29a is in physical contact with the top surface of the dielectric layer 18. In some embodiments, the bottom surface of the conductive layer 30 and the bottom surface of the adhesion promoter layer 29a are substantially coplanar with the bottom surface of the etching stop layer 23.

In some embodiments, the adhesion promoter layer 29a is not in contact with the contact 22, and is separated from the contact 22 by the conductive layer 30. The adhesion promoter layer 29a may be electrically connected to the contact 22 through the conductive layer 30. In other word, the conductive layer 30 penetrates through the dielectric layer 24, the etching stop layer 23 and the adhesion promoter layer 29a to contact with the top surface of the contact 22.

The adhesion promoter layer 29a may help to improve the adhesion between the conductive layer 30 and the dielectric layer 24 and between the conductive layer 30 and the etching stop layer 23, and may also serve as diffusion barrier for preventing the metal atoms of the conductive layer 30 from diffusing to the adjacent dielectric layer 24 or/and the etching stop layer 23.

Still referring to FIG. 1H, in the first embodiment, the contact 22 is with barrier layer, while the via 32 is free of a conventional barrier layer (that is, barrierless), but the disclosure. In some other embodiments, both the contact 22 and the via 32 are barrierless.

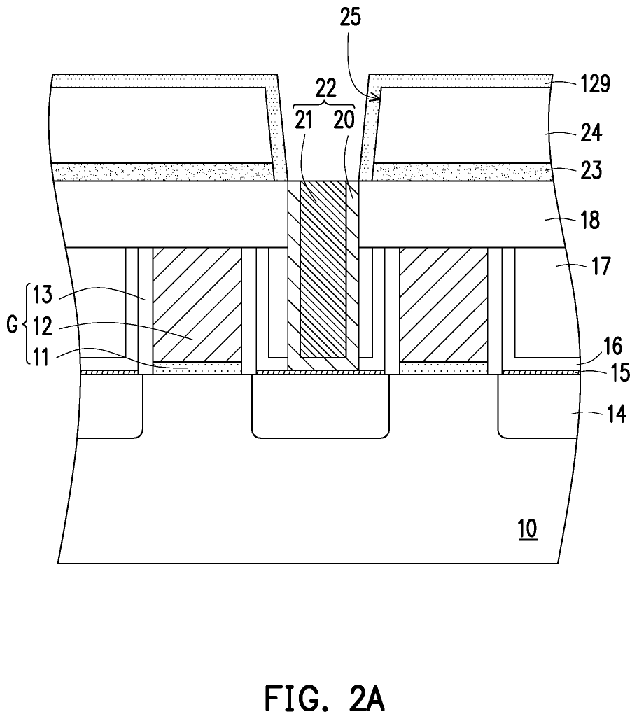

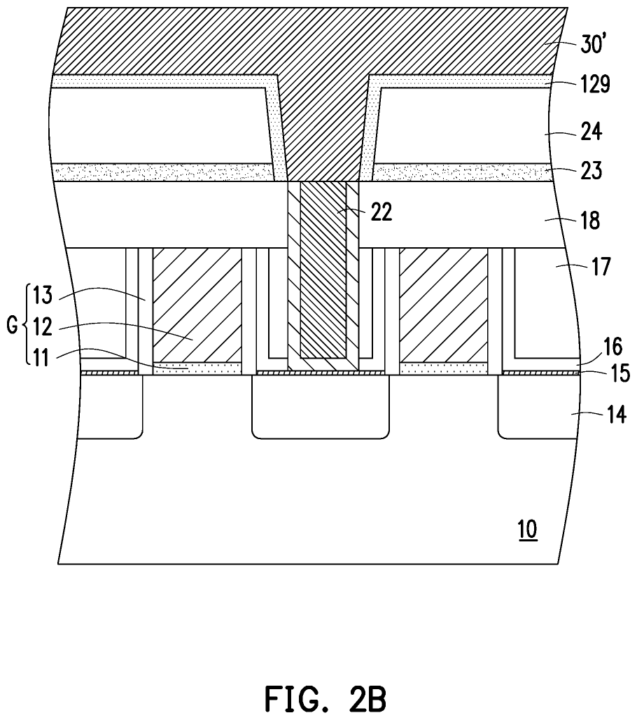

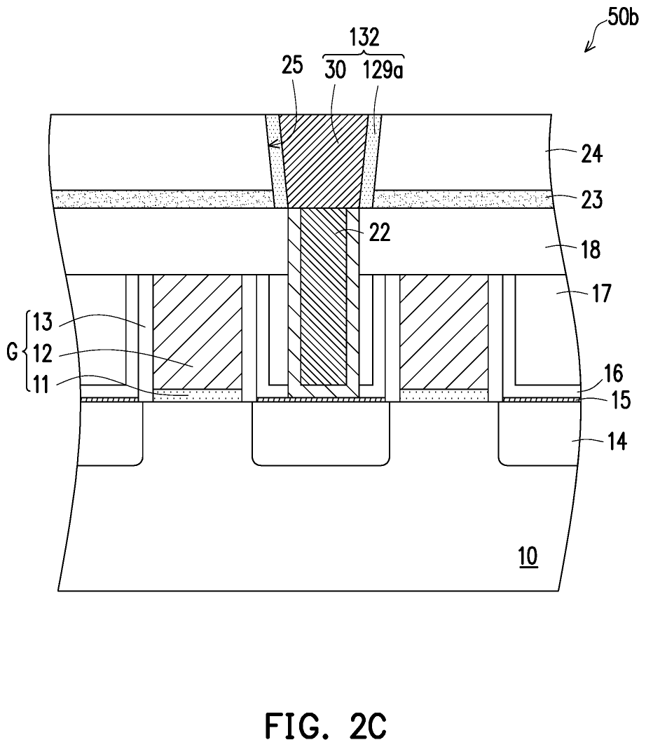

FIG. 2A to FIG. 2C are schematic cross-sectional views illustrating a method of forming a semiconductor device according to a second embodiment of the disclosure. The second embodiment differs from the first embodiment in that no inhibitor layer is formed, and the selective deposition of the adhesion promoter layer is implemented through the different properties of the contact 22 and the dielectric layers 18/24 and the etching stop layer 23.

Referring to FIG. 1C and FIG. 2A, processes similar to FIG. 1C is performed to form a via hole 25 in the etching stop layer 23 and the dielectric layer 24. The via hole 25 expose the top surface of the contact 22, a portion of a top surface of the dielectric layer 18, and sidewalls of the dielectric layer 24 and the etching stop layer 23. The materials of the dielectric layers 18/24, the etching stop layer23 and the contact 22 are substantially the same as those described in the first embodiment, which are not described again.

In some embodiments, after the via hole 25 is formed, a selective deposition process is performed to form an adhesion promoter layer 129 on the top surface of the dielectric layer 18, the sidewalls of the etching stop layer 23, the sidewalls of the dielectric layer 24 exposed by the via hole 25, and on the top surface of the dielectric layer 24, and the selective deposition process is performed without forming an inhibitor layer on the contact 22. In some embodiments, the selective deposition process includes a pulsed mode ALD or CVD, for example. The selective deposition process may be performed by using a precursor and a reaction gas to react to form the adhesion promoter layer 129. In some embodiments, the reaction gas adsorbs on the exposed surface of the dielectric layer 18, etching stop layer 23 and the dielectric layer 24 and does not adsorb on the exposed surface of the contact 22, due to the different properties of the dielectric layer 18/etching stop layer 23/the dielectric layer 24 and the contact 22.

For example, the materials of the dielectric layer 18, the etching stop layer 23 and the dielectric layer 24 have hydrophilic property, on which the reaction gas is easy to adsorb. The materials of the contact 22 have a weaker hydrophilic property than that of the dielectric layers 18/24 and the etching stop layer 23, or the materials of the contact 22 do not have hydrophilic properties, such as have hydrophobic properties. In some embodiments, the reaction gas may include oxygen (O₂) or ammonia (NH₃). The oxygen or ammonia absorbs on the exposed dielectric layer 18, etching stop layer 23 and dielectric layer 24 due to the hydrophilic properties thereof, and does not absorb on the contact 22 because the contact 22 have weaker hydrophilic property or does not have the hydrophilic property. As such, the precursor reacts with the reaction gas absorbed on the dielectric layer 18, etching stop layer 23 and dielectric layer 24, and the adhesion promoter layer 129 is thus formed. Since the reaction gas is merely absorbed on the dielectric layer 18, the etching stop layer 23 and the dielectric layer 24 without absorbing on the contact 22, the adhesion promoter layer 129 is selectively formed on the top surface of the dielectric layer 18, the sidewalls of the etching stop layer 23 and the dielectric layer 24 without forming on the top surface of the contact 22.

In some embodiments in which the adhesion promoter layer 129 includes TiO₂, the precursor of the selective deposition process for forming the adhesion promoter layer 129 may include TiCl₄, TDMAT, TDEAT, TEMAT, and the reaction gas includes O₂, wherein O₂ adsorbs on the exposed dielectric layer 18, etching stop layer 23 and dielectric layer 24 without adsorbing on the contact 22.

In some embodiments in which the adhesion promoter layer 129 includes HfO₂, the precursor of the selective deposition process may include HfCl₄, [(CH₂CH₃)₂N]₄Hf or the like, and the reaction gas includes O₂, wherein O₂ adsorbs on the exposed dielectric layer 18, etching stop layer 23 and dielectric layer 24 without adsorbing on the contact 22.

In some embodiments in which the adhesion promoter layer 129 includes RuO₂, the precursor of the selective deposition process may include [Ru(tfa)₃], cyclo hexdiene or carbonyl based Ru precursors like Ru(CO)x or [Ru(CO)₃C₆H₈]₇, [Ru(acac)₃], [Ru(CO)₂ (hfac)₂] or the like or combinations thereof, and the reaction gas include O₂, wherein O₂ adsorbs on the exposed dielectric layer 18, etching stop layer 23 and dielectric layer 24 without adsorbing on the contact 22.

In some embodiments in which the adhesion promoter layer 129 includes other metal oxide such as Al₂O₃, WOₓ, Y₂O₃, La₂O₃, MgOₓ, LiOₓ, V₂O₅, Yb₂O₃, MoOₓ, GdOₓ, the selective deposition process is similar to that described above using oxygen as the reaction gas.

In some embodiments in which the adhesion promoter layer 129 includes a nitride, the selective deposition process uses ammonia (NH₃) as the reaction gas, and the selective deposition process is performed in a way similar to that described above.

Referring to FIG. 2B, a conductive material layer 30′ is formed over the substrate 10 by CVD, ALD, PVD, ECP, ELD, or the like. The material of the conductive material layer 30′ is similar to, the same as or different from those described in the first embodiment. In some embodiments, the conductive material layer 30′ and the adhesion promoter layer 129 may be in-situ formed. For example, the conductive material layer 30′ includes a metal (such as W), and the adhesion promoter layer 129 includes a metal oxide (such as WOₓ) correspond to the metal of the conductive material layer 30′, the conductive material layer 30′ and the adhesion promoter layer 129 may be formed in a same chamber of the a deposition machine by the following process. In one embodiment, process gases (precursor) such as WF₆ and O₂ are introduced into the deposition chamber to form the metal oxide WOₓ of the adhesion promoter layer 129, thereafter, O₂ source gas is closed to stop introducing O₂ into the chamber, and keep introducing the precursor WF₆ to form the metal W of the conductive material layer 30′.

Referring to FIG. 2B to FIG. 2C, thereafter, a planarization process is performed to remove the conductive material layer 30′ and the adhesion promoter layer 129 over the top surface of the dielectric layer 24 in some embodiments. An adhesion promoter layer 129 and a conductive layer 30 remain in the via hole 25 to constitute a via 132. A semiconductor device 50b is thus completed. The semiconductor device 50b is similar to the semiconductor device 50a, except that the forming method of the adhesion promoter layer 129a is different from the adhesion promoter layer 29a. The other features of the semiconductor device 50b are substantially the same as those of the semiconductor device 50a, which are not described again.

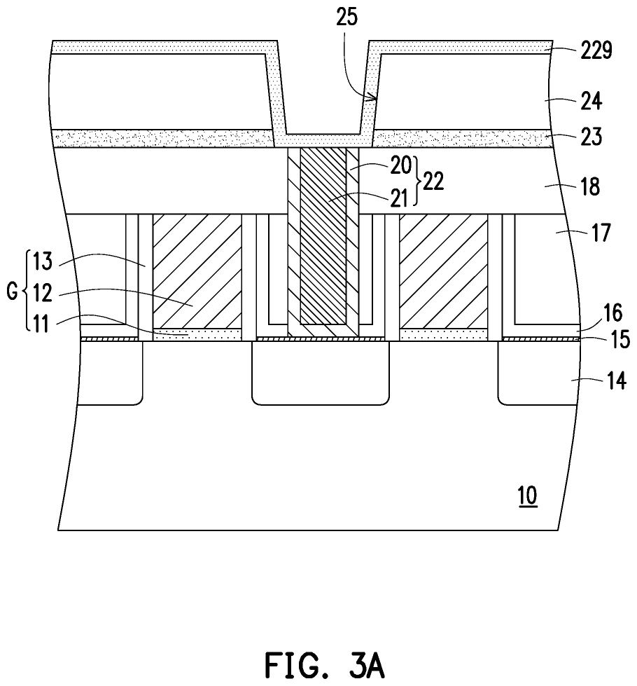

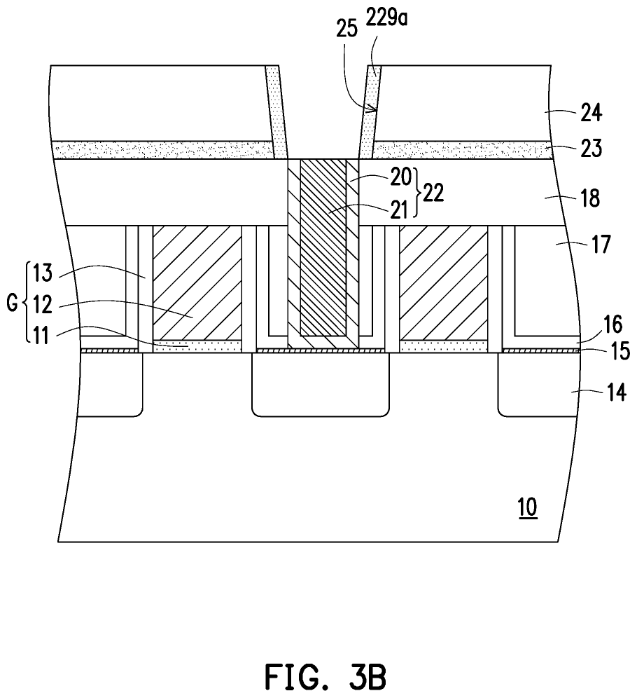

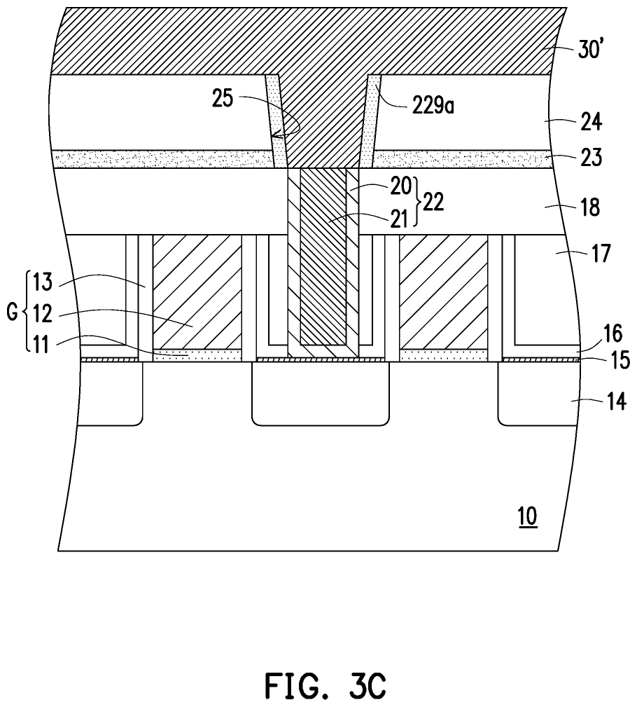

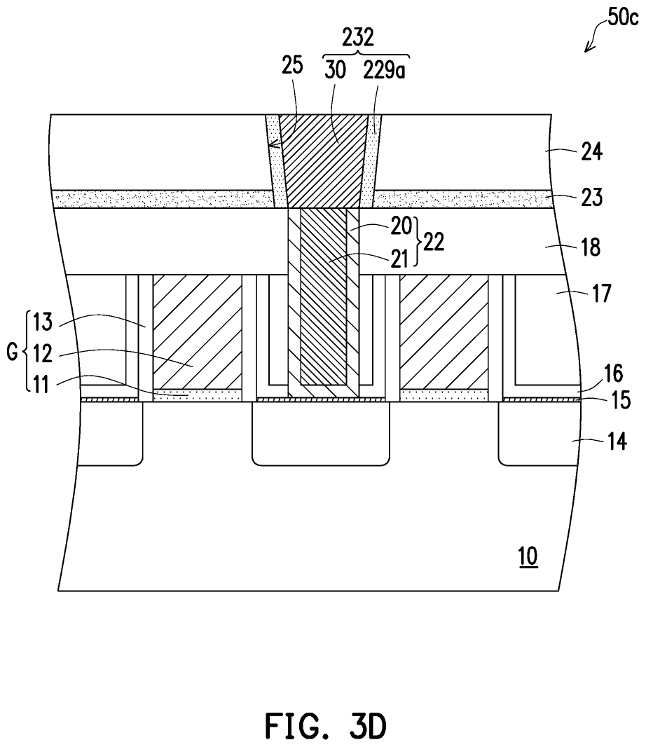

FIG. 3A to FIG. 3D are schematic cross-sectional view illustrating a method of forming a semiconductor device according to a third embodiment of the disclosure. The third embodiment differs from the foregoing embodiments in that the adhesion promoter layer is formed by a blanket deposition process and an etching back process.

Referring to FIG. 3A, in some embodiments, after the via hole 25 is formed, an adhesion promoter layer 229 is blanket deposited over the substrate 10. The deposition process includes CVD, ALD, or the like or combinations thereof. The adhesion promoter layer 229 covers the top surface of the dielectric layer 24 and fills in the via hole 25 to cover the inner surface of the via hole 25. In other words, the top surface of the contact 22, a portion of the top surface of the dielectric layer 18, the sidewalls of the etching stop layer 23, the sidewalls and the top surface of the dielectric layer 24 are covered by the adhesion promoter layer 229.

Referring to FIG. 3A to FIG. 3B, a portion of the adhesion promoter layer 229 is removed by an etching process (such as anisotropic etching process) to form an adhesion promoter layer 229a. In some embodiments, the adhesion promoter layer 229 is etched back, such that the horizontal portions thereof are removed, that is, the portions of the adhesion promoter layer 229 on the top surface of the dielectric layer 24 and at the bottom of the via hole 25 are removed, and the portion of the adhesion promoter layer 229 on sidewalls of the via hole 25 remain.

Referring to FIG. 3B, in some embodiments, the adhesion promoter layer 229a is disposed on sidewalls of the via hole 25, the top surface of the adhesion promoter layer 229a may be substantially coplanar with the top surface of the dielectric layer 24. The adhesion promoter layer 229a covers a portion of the top surface of the dielectric layer 18, and may or may not cover the top surface of the contact 22. In other words, the top surface of the contact 22 is at least partially exposed by the adhesion promoter layer 229a. In some embodiments, the adhesion promoter layer 229a is not in contact with the top surface of the contact 22, and the top surface of the contact 22 is completely exposed by the adhesion promoter layer 229a. In some other embodiments, a small portion of the top surface of the contact 22 may be covered by the adhesion promoter layer 229a.

Referring to FIG. 3C and FIG. 3D, processes similar to those from FIG. 1G to FIG. 1H are performed, a conductive material layer 30′ is formed over the substrate 10. The conductive material layer 30′ covers the top surface of the dielectric layer 24 and fills into the via hole 25. In this embodiment, the conductive material layer 30′ is in contact with the top surface of the dielectric layer 24. Thereafter, a planarization process is performed to remove a portion of the conductive material layer 30′ over the top surface of the dielectric layer 24, and a conductive layer 30 in the via hole 25 is remained. The conductive layer 30 and the adhesion promoter layer 229a constitute a via 232. A semiconductor device 50c is thus formed. The semiconductor device 50c is similar to the semiconductor device 50a, expect that the forming method of the adhesion promoter layer 229a is different from that of the adhesion promoter layer 29a, and the adhesion promoter layer 229a may be in contact with the contact 22 in some embodiments.

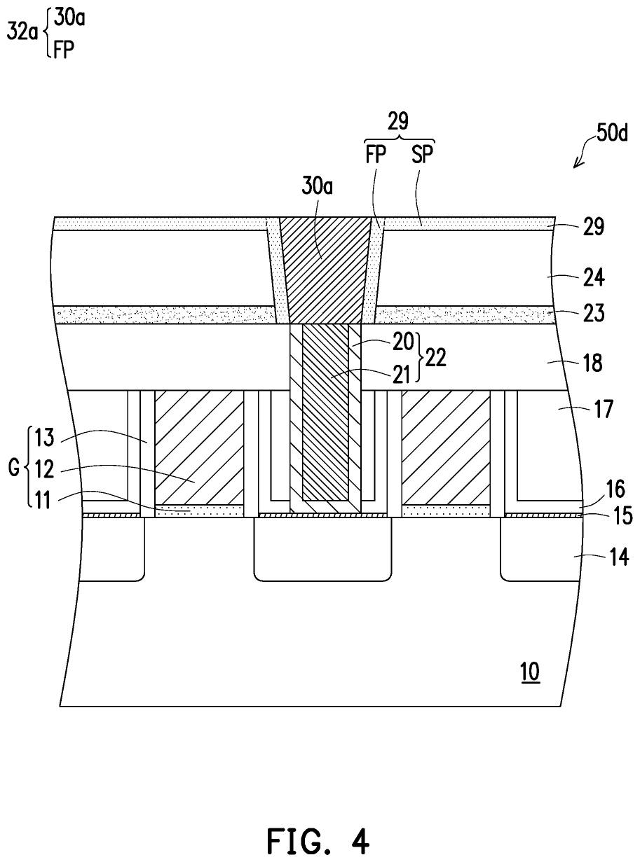

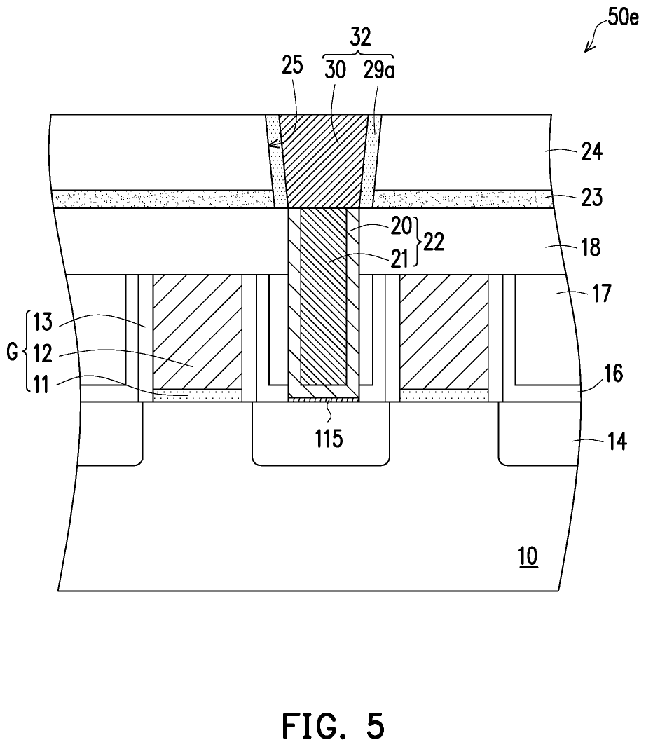

FIG. 4 and FIG. 5 are schematic cross-sectional views illustrating semiconductor devices according to some embodiments of the disclosure.

In the forgoing first and second embodiments, the adhesion promoter layer 29/129 over the top surfaces of dielectric layer 24/124 are removed during the planarization process, but the disclosure is not limited thereto.

Referring to FIG. 1G and FIG. 4, in some embodiments in which the adhesion material layer 29 is made of a dielectric layer, after the conductive material layer 30′ is formed, a planarization process is performed to remove the conductive material layer 30′ over the top surface of the adhesion promoter layer 29, so as to form a conductive layer 30a. The planarization process may include a CMP process, and the adhesion promoter layer 29 may serve as a CMP stop layer during the CMP process. In some embodiments, the top surface of the conductive layer 30a is substantially coplanar with the top surface of the adhesion promoter layer 29.

Referring to FIG. 4, a semiconductor device 50d is thus formed. The semiconductor device 50d includes the substrate 10, the gate stack G, the S/D regions 14, the etching stop layer 16, the dielectric layer 17, the dielectric layer 18, the etching stop layer 23, the dielectric layer 24, the contact 22, the conductive layer 30a and the adhesion promoter layer 29. The conductive layer 30a is in electrically contact with the contact 22. The adhesion promoter layer 29 is electrically isolated from the conductive layer 30a and the contact 22.

In some embodiments, the adhesion promoter layer 29 and the conductive layer 30a are located in the via hole 25 and protrude from the top surface of the dielectric layer 24. In some embodiments, the top surface of the dielectric layer 24 is covered by the adhesion promoter layer 29. The top surface of the conductive layer 30a is coplanar with the top surface of the adhesion promoter layer 29 and higher than the top surface of the dielectric layer 24. In other words, the adhesion promoter layer 29 surrounds the sidewalls of the conductive layer 30a and further extends to cover the top surface of the dielectric layer 24.

From another point of view, the adhesion promoter layer 29 includes a first portion FP and a second portion SP connected to each other. The first portion FP is located in the via hole 25 and protrudes from the top surface of the dielectric layer 24, surrounding the sidewalls of the conductive layer 30a. The first portion FP is located between the conductive layer 30a and the etching stop layer 23, between the conductive layer 30a and the dielectric layer 24, and between the conductive layer 30a and the second portion SP. In some embodiments, the conductive layer 30a and the first portion FP of the adhesion promoter layer 29 constitute a via 32a. The top surface of the via 32a protrudes from the top surface of the dielectric layer 24.

The second portion SP is located on the top surface of the dielectric layer 24 and laterally aside the via 30a, extending in a direction parallel with the top surface of the substrate 10. In some embodiments, since the first portion FP and the second portion SP are comprised in the same layer of the adhesion promoter layer 29, no interface is existed between the first portion FP and the second portion SP, that is, no interface is existed between the via 32a and the second portion SP.

It is noted that, in the embodiments in which the adhesion promoter layer 29 is made of dielectric material, the planarization process may be stopped at the top surface of the adhesion promoter layer 29, as shown in FIG. 4, and may also be stopped at the top surface of the dielectric layer 24, as shown in FIG. 1H. That is, the adhesion promoter layer 29 over the top surface of the dielectric layer 24 may or may not be removed during the planarization process. In the embodiments in which the adhesion promoter layer 29 is made of conductive material, the planarization process will remove the adhesion promoter layer 29 over the top surface of the dielectric layer 24.

The concept of the embodiment shown in FIG. 4 may also be applied to the second embodiment. Referring to FIG. 2B, in the second embodiment, after the conductive material layer 30′ is formed, the planarization process may remove the conductive material layer 30′ over the top surface of the adhesion promoter layer 129 and not remove the adhesion promoter layer 129.

In the foregoing embodiments, the silicide layer 15 is formed after the spacer 13 is formed, as shown in FIG. 1H, FIG.2C, FIG. 3D and FIG. 4, the silicide layer 15 covers a portion of the top surface of the S/D region 14. The top surface of the silicide layer 15 is covered by the etching stop layer 16 and the contact 22, the sidewalls of the silicide layer 15 is in contact with the spacer 13 of the gate stack G. A portion of the silicide layer 15 is located between the etching stop layer 16 and the S/D region 14. However, the disclosure is not limited thereto.

FIG. 5 illustrates a semiconductor device 50e according to some other embodiments of the disclosure. In some embodiments, a silicide layer 115 may be formed on the S/D region 14 after the contact hole 19 (FIG. 1B) is formed. Referring to FIG. 5, in some embodiments, the sidewalls of the silicide layer 115 is aligned with the sidewalls of the contact 22. The silicide layer 115 is not in contact with the spacer 13 of the gate stack G, and is separated from the spacer 13 by the etching stop layer 16 therebetween. The top surface of the silicide layer 115 is covered by the contact 22, and the sidewalls of the silicide layer 115 are covered by the etching stop layer 16. A portion of the top surface of the S/D region 14 is covered by the silicide layer 115 and the etching stop layer 16.

In the embodiments of the disclosure, the semiconductor devices 50a-50e may be planar transistors, FinFETs, gate-all-around transistors, nanowire transistors, multiple-gate transistors, or the like, and the disclosure is not limited thereto. The semiconductor device 50a-50e may be further subjected to variety of processes, such that a plurality of (multi-layers of) metal lines and vias and dielectric layers are formed over the via 32/32a/132/232 and the dielectric layer 24/124, so as to form an interconnection structure over the substrate 10. In some embodiments, the metal lines are extending on top surfaces of the dielectric layers in a horizontal direction parallel with a top surface of the substrate 10, for example. The vias vertically penetrates through the dielectric layers to connect the metal lines in different layers.

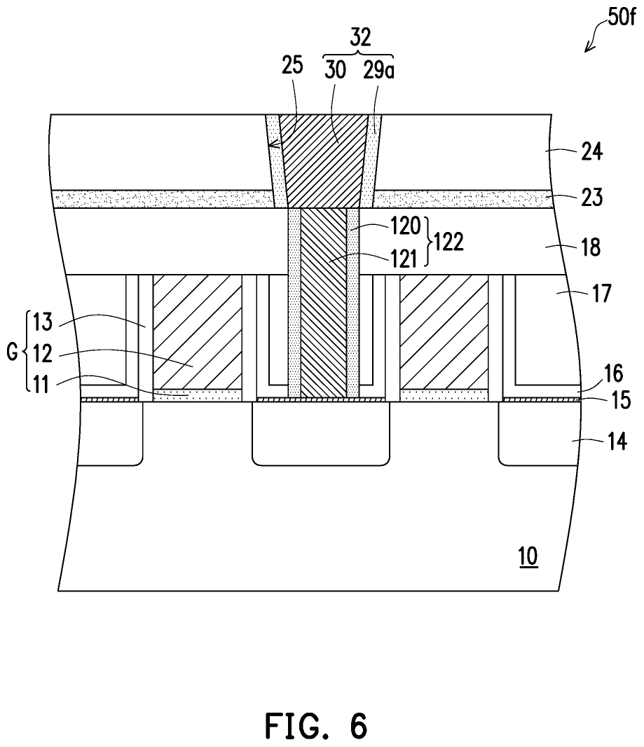

In the foregoing embodiments, the via are formed without barrier layer surrounding the conductive layer, and the adhesion promoter layer is formed on sidewalls of the conductive layer. In some embodiment, the resistivity of barrierless via of the disclosure is lower than a conventional via having barrier layer. In the illustrated embodiments, the via is free of barrier layer (that is, barrierless), while the contact includes a barrier layer, but the disclosure is not limited thereto. The barrierless process may also be applied to the contact. As shown in FIG. 6, in some embodiments, a semiconductor device 50f may include a contact 122 and a via 32, both the contact 122 and the via 32 are free of a barrier layer. In some embodiments, the contact 122 includes an adhesion promoter layer 120 and a conductive layer 121. The adhesion promoter layer 120 and the conductive layer 121 may be formed by similar processes of the adhesion promoter layer and conductive layer of the via as described above. In this embodiment, the conductive layer 121 is in direct contact with the silicide layer 15 on the S/D region 14. The adhesion promoter layer 120 is located on sidewalls of the conductive layer 121.

It is noted that, the barrierless process of the disclosure may be applied to contact, via or/and the other metal lines or vias of the interconnection structure to be formed over the substrate 10. In some embodiments, all of the metal features (metal lines, vias, and contacts) of the interconnection structure are barrierless. In some embodiments, some of the metal features of the interconnection structure are barrierless, and others are formed with barrier layer.

In some embodiments of the disclosure, at least the via is formed free of barrier layer, and the adhesion promoter layer is selectively formed at least between the conductive layer and the adjacent dielectric layers. As such, the resistivity of the metal features included in the interconnections of the semiconductor device is reduced. At the same time, the adhesion promoter layer help to improve the adhesion between the conductive layer and the adjacent dielectric features, thus avoiding metal peeling issue. In addition, the adhesion promoter layer may also present the metal diffusion of the conductive layer. As a result, the performance and the yield of the semiconductor device are improved, and defects thereof are reduced.

In accordance with some embodiments of the disclosure, a semiconductor device includes a substrate, a gate stack and a first dielectric layer over the substrate, a source/drain (S/D) region, a contact, and a via. The first dielectric layer is laterally aside and over the gate stack. The S/D region is located in the substrate on sides of the gate stack. The contact penetrates through the first dielectric layer to electrically connect to the S/D region. The via penetrates through a second dielectric layer to connect to the contact. the via includes a conductive layer and an adhesion promoter layer on sidewalls of the conductive layer. The conductive layer is in contact with the contact.

In accordance with alternative embodiments of the disclosure, a semiconductor device includes a substrate, a gate stack and a first dielectric layer over the substrate, a contact, and a conductive layer. The first dielectric layer is laterally aside and over the gate stack. The contact penetrates through the first dielectric layer to electrically connect to the substrate. The conductive layer penetrates through a second dielectric layer and an adhesion promoter layer to connect to the contact. The adhesion promoter layer is laterally between the conductive layer and the second dielectric layer.

In accordance with some embodiments of the disclosure, a method of manufacturing a semiconductor device includes the following processes. A substrate having a gate stack formed thereon is provided. A first dielectric layer is formed aside and over the gate stack. A contact is formed to penetrate through the first dielectric layer to connect to the substrate. A second dielectric layer is formed over the first dielectric layer. The second dielectric layer is patterned to form a via hole to expose a top surface of the contact and a portion of a top surface of the first dielectric layer. An adhesion promoter layer is selectively deposited on the portion of the top surface of the first dielectric layer and sidewalls of the second dielectric layer exposed by the via hole. A conductive layer is formed within the via hole to electrically contact with the contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a gate stack and a first dielectric layer over the substrate, wherein the first dielectric layer is laterally aside and over the gate stack;
a source/drain (S/D) region, located in the substrate on sides of the gate stack;
a contact, penetrating through the first dielectric layer to electrically connect to the S/D region; and
a via, penetrating through a second dielectric layer to connect to the contact, the via comprises a conductive layer and an adhesion promoter layer on sidewalls of the conductive layer,
wherein the conductive layer is in contact with the contact.

2. The semiconductor device of claim 1, wherein the adhesion promoter layer is separated from the contact by the conductive layer.

3. The semiconductor device of claim 1, wherein a bottom surface of the adhesion promoter layer is coplanar with a bottom surface of the conductive layer.

4. The semiconductor device of claim 1, wherein the adhesion promoter layer further extend to cover a top surface of the second dielectric layer.

5. The semiconductor device of claim 5, wherein the conductive layer protrudes from the top surface of the second dielectric layer.

6. The semiconductor device of claim 1, wherein the contact comprises a barrier layer and a conductive feature on the barrier layer, the barrier layer surrounds sidewalls and a bottom surface of the conductive feature.

7. The semiconductor device of claim 6, wherein a material of the adhesion promoter layer is different from a material of the barrier layer.

8. The semiconductor device of claim 1, wherein the adhesion promoter layer comprises a conductive metal oxide or a dielectric material.

9. A semiconductor device, comprising:
a substrate;
a gate stack and a first dielectric layer over the substrate, wherein the first dielectric layer is laterally aside and over the gate stack;
a contact, penetrating through the first dielectric layer to electrically connect to the substrate; and
a conductive layer, penetrating through a second dielectric layer and an adhesion promoter layer to connect to the contact, wherein the adhesion promoter layer is laterally between the conductive layer and the second dielectric layer.

10. The semiconductor device of claim 9, further comprising an etching stop layer between the first dielectric layer and the second dielectric layer, wherein a bottom surface of the conductive layer and a bottom surface of the adhesion promoter layer are coplanar with a bottom surface of the etching stop layer.

11. The semiconductor device of claim 9, wherein the adhesion promoter layer further extent to cover a top surface of the second dielectric layer.

12. The semiconductor device of claim 9, wherein the first dielectric layer and the second dielectric layer have hydrophilic property.

13. The semiconductor device of claim 9, wherein the semiconductor device is a planar transistor or a FinFET.

14. A method of manufacturing a semiconductor device, comprising:
providing a substrate having a gate stack formed thereon;
forming a first dielectric layer aside and over the gate stack;
forming a contact penetrating through the first dielectric layer to connect to the substrate;
forming a second dielectric layer over the first dielectric layer;
patterning the second dielectric layer to form a via hole to expose a top surface of the contact and a portion of a top surface of the first dielectric layer.
selectively depositing an adhesion promoter layer on the portion of the top surface of the first dielectric layer and sidewalls of the second dielectric layer exposed by the via hole; and
forming a conductive layer within the via hole to electrically contact with the contact.

15. The method of claim 14, wherein the selectively depositing the adhesion promoter layer further comprises:
forming a self-aligned monolayer on the top surface of the contact before the selectively depositing, wherein a molecule of the self-aligned monolayer comprises a head group having a specific affinity for the contact, and a functional group inhibiting a deposition of the adhesion promoter layer over the contact; and
removing the self-aligned monolayer after the selectively depositing.

16. The method of claim 14, wherein the selectively depositing the adhesion promoter layer is performed by a reaction of a precursor and a reaction gas, wherein the reaction gas absorbs on the portion of the top surface of the first dielectric layer and the sidewalls of the second dielectric layer exposed by the via hole, without absorbing on the contact.

17. The method of claim 16, wherein the first dielectric layer and the second dielectric layer have hydrophilic property, and the reaction gas comprises oxygen or ammonia.

18. The method of claim 14, wherein the selectively depositing the adhesion promoter layer comprises:
blanket depositing an adhesion promoter material layer over the substrate, the adhesion promoter material layer covers a top surface of the second dielectric layer and an inner surface of the via hole; and
performing an etching back process to remove horizontal portions of the adhesion promoter material layer.

19. The method of claim 14, wherein the adhesion promoter layer is further formed over a top surface of the second dielectric layer; and forming the conductive layer comprises:
forming a conductive material layer over the substrate, wherein the conductive material layer covers a top surface of the adhesion promoter layer and fills in the via hole; and
performing a planarization process to remove a first portion the conductive material layer over the top surface of the adhesion promoter layer.

20. The method of claim 19, wherein the planarization process further removes a second portion of the conductive layer and a portion of the adhesion promoter layer over the top surface of the second dielectric layer.
